(19) United States
(12) Patent Application Publication
(10) Pub. No.: US 2025/0047276 A1
(43) Pub. Date: Feb. 6, 2025

(54) REAL-TIME MONITORING AND PROTECTION CIRCUIT FOR GAN TRANSISTORS TO PROTECT FROM AND MONITOR THE TRAPPING PHENOMENON

(71) Applicant: COMMISSARIAT A L'ENERGIE ATOMIQUE ET AUX ENERGIES ALTERNATIVES, Paris (FR)

(72) Inventors: Van-Sang NGUYEN, Grenoble Cedex 09 (FR); Stéphane CATELLANI, Grenoble Cedex 09 (FR); Anthony BIER, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/719,784

(22) PCT Filed: Dec. 17, 2021
(86) PCT No.: PCT/FR2021/052385

§ 371 Date: Jun. 13, 2024

(51) Int. Cl. H03K 17/082; H03K 17/18

(52) U.S. Cl. CPC H03K 17/0822; H03K 17/18

(57) ABSTRACT

An electronic device provided with transistors containing GaN, and including a control circuit configured to evaluate the drain source resistance in the on state of at least one first transistor out of the transistors.

### TECHNICAL FIELD

The present application relates to the field of circuits provided with transistors containing GaN and provided with means for preventing the phenomenon of current collapse in these transistors.

It relates in particular to the circuits provided with HEMT (“High Electron Mobility Transistor”) transistors and applies in particular to the power circuits such as power inverters or DC/DC and DC/AC converters.

### PRIOR ART

The transistors containing GaN of the HEMT type have the advantage in particular of supporting high current densities as well as high voltages in the off state. They have uses in the field of power circuits such as electric energy converters and power inverters.

However, these transistors, and more generally the transistors having a channel structure comprising a layer of GaN, are subject to a phenomenon of current collapse caused by electron traps in their semiconductor structure. Such a phenomenon is mentioned for example in the document by T. Hasan, “Mechanism and Suppression of Current Collapse in AlGaN/GaN High Electron Mobility Transistors” PhD thesis-University of Fukui, Japan 2013.

The origin of such traps can be a consequence of several factors, for example such as crystalline defects, dislocations, or the presence of impurities. Such traps can also be located in the interface between various semiconductor materials and passivation layers. In the transistors containing GaN, the traps are mainly located in the GaN or in the interface between this layer and another wide-bandgap material for example containing AlGaN.

The phenomenon of current collapse significantly affects circuits in particular the power circuits such as converters and power inverters, furthermore when operation at high temperature and at low operating voltage is required. This can even cause thermal breakage of the components.

It is therefore sought to monitor and prevent this phenomenon in the circuits provided with such components.

### DISCLOSURE OF THE INVENTION

Thus, an embodiment of the present invention relates to an electronic device provided with transistors containing GaN, comprising a control circuit configured to evaluate the drain source resistance in the on state of at least one first transistor out of said transistors.

The control circuit can be provided:
with a first circuit for measuring drain source voltage in the on state of the first transistor, the first measurement circuit comprising a first operational amplifier, in particular mounted in differential mode, configured to produce at the output a first output voltage proportional to a difference in potentials between a drain electrode potential of the first transistor placed in the on state and a source electrode potential of the first transistor placed in the on state,
with a first switch element arranged between a given electrode out of said source and drain electrodes of the first transistor and a first input of the first amplifier, the first switch element being configured to couple the given electrode to the first input of the first amplifier consecutively to a placement of the first transistor in the on state,
with a circuit branch in which a load current that is an image of a current passing through the first transistor in the on state is capable of circulating,
with an evaluation stage configured to, on the basis of said load current and said output voltage, produce a first evaluation signal representative of the ratio between said output voltage and said load current.

Advantageously, the evaluation stage of the control circuit is provided with a digital calculation module integrated into a microcontroller or into an integrated circuit having a network of programmable cells and/or includes an analogue divider or an analogue multiplier.

According to an advantageous embodiment, the control circuit can be further provided with a protection circuit, the protection circuit comprising a first comparator to compare the first evaluation signal to a given threshold, the protection circuit being configured to, when the first evaluation signal exceeds the given threshold, emit a deactivation signal so as to maintain said first transistor off.

Thus, besides a simple monitoring of the change in the dynamic drain source resistance, a protection of the transistor containing GaN can be implemented.

The control circuit can be provided with a first gate pilot circuit producing said first control signal, the deactivation signal being emitted at the input of said first gate pilot circuit.

According to one possible embodiment wherein among said transistors at least one second transistor is coupled to the first transistor, a gate of the second transistor being controlled by a second control signal, the second control signal being except for dead times in phase opposition to the first control signal, said circuit branch being arranged between the first transistor and the second transistor so that the load current is the image of the current passing through the second transistor when the second transistor is in the on state, said control circuit may further provided:
with a second circuit for measuring drain source voltage in the on state of the second transistor, the second measurement circuit comprising an operational amplifier, in particular mounted in differential mode, called second amplifier to produce at the output an output voltage proportional to a difference in potential between a drain electrode potential of the second transistor placed in the on state and a source electrode potential of the second transistor placed in the on state,
with a second switch element arranged between the source electrode of the second transistor and an input of the second amplifier, the second switch element being configured to couple the source electrode of the second transistor and the input of the second amplifier consecutively to a placement of the second transistor in the on state,
said evaluation stage of the control circuit being further configured to, on the basis of said load current and said output voltage, produce a second evaluation signal representative of the ratio between the output voltage of the second transistor and said load current.

Advantageously, the control circuit is provided with a protection circuit and the gate of the second transistor is controlled by a second gate pilot circuit. Advantageously, the protection circuit is provided with a second comparator to compare said second evaluation signal to another given threshold, the protection circuit being further configured to, when the second evaluation signal exceeds said other given threshold, emit a second deactivation signal at the input of a second gate pilot circuit so as to maintain said second transistor off.

According to one possible embodiment, the first switch element is controlled by a measurement triggering signal, the control circuit further comprising a stage for controlling the signal of the first control signal and of the measurement triggering signal to, consecutively to a change in state of the first control signal turning the first transistor on, trigger, after a first determined delay after this change, a state modification of the measurement triggering signal so as to turn the first switch element on and to, consecutively to a new state modification of the measurement triggering signal turning the first switch element on, trigger a new state change of the control signal turning the first transistor off.

Thus, advantageously, a measurement of drain source resistance is carried out on a GaN transistor only when this transistor is turned on.

According to an advantageous embodiment, the first amplifier is powered via an external battery.

According to another aspect the present invention relates to a power electronic device such as a power inverter or a converter provided with a device having transistors as defined above, the first transistor belonging to one arm of the power inverter or a switching cell of the converter or, if necessary, the first transistor and the second transistor belonging to the same arm of the power inverter or to the same switching cell of the converter.

### BRIEF DESCRIPTION OF THE DRAWINGS

The present invention will be better understood on the basis of the following description and the appended drawings in which:

FIG. 1 is used to illustrate a device provided with wide-bandgap transistors associated with a circuit for controlling the dynamic drain source resistance of wide-bandgap transistors.

FIG. 2 given an example of an operating chronogram of the device of FIG. 1 with the signals for activation of the transistors and the signals for controlling switch elements of the associated control circuit.

FIG. 3 is used to illustrate an example of a control stage of the control circuit configured to evaluate a dynamic drain source resistance of the wide-bandgap transistors and control the signals for activation of the wide-bandgap transistors according to this activation.

FIG. 4 is used to illustrate an example of a protection circuit for deactivating the wide-bandgap transistors when their dynamic drain source resistance exceeds a given threshold.

FIG. 5 is used to illustrate a structure of an HEMT transistor containing GaN, a control circuit of which as implemented according to the invention allows to evaluate the dynamic drain source resistance.

Identical, similar or equivalent parts of the various drawings carry the same numerical references so as to facilitate the passage from one drawing to the other.

The various parts shown in the drawings are not necessarily on a uniform scale, to make the drawings more readable.

### DETAILED DISCLOSURE OF SPECIFIC EMBODIMENTS

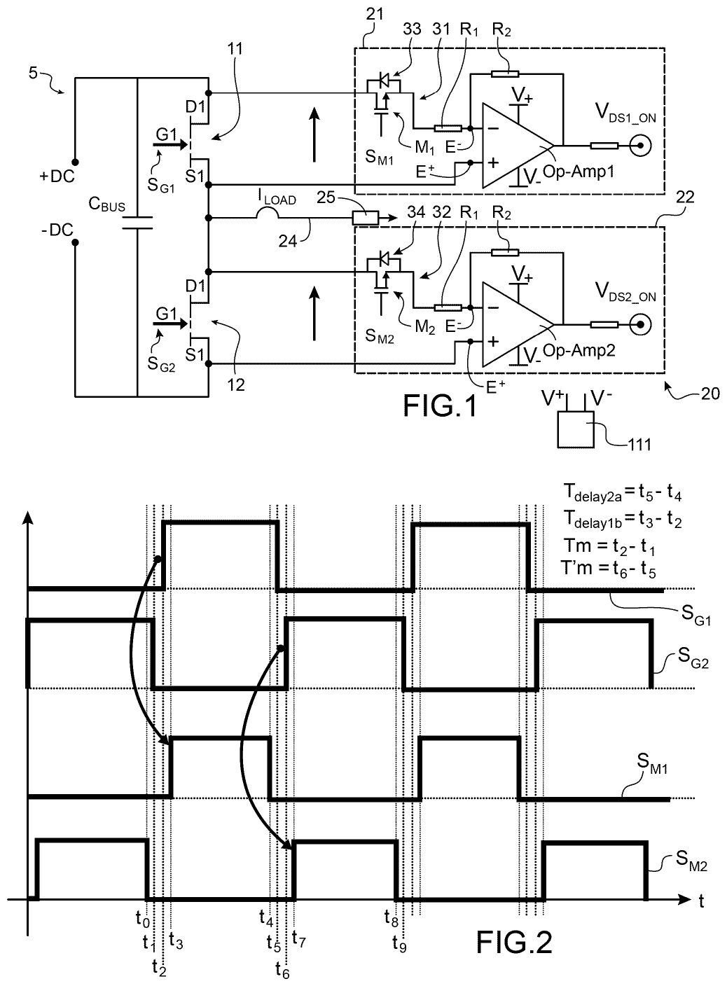

Reference is now made to FIG. 1 used to illustrate a measurement stage 20 of a circuit for controlling dynamic drain source resistance of transistors 11, 12 containing GaN, that is to say made of a semiconductor structure provided with at least one layer of GaN to form a heterojunction.

The transistors 11, 12 are in this example HEMT transistors belonging to a power electronic device and in particular to a power inverter 5 allowing to generate voltages and alternating currents from a source of electric energy with DC voltage.

The stage 20 allows to carry out a measurement and a monitoring of a power-inverter arm on the basis of drops in drain source voltage in the transistors 11, 12 containing GaN when the latter are placed in the on state.

The transistors 11, 12, the respective dynamic drain source resistances R_{DS_ON1}, R_{DS_ON2} of which in the on state are monitored, belong here to the same power-inverter arm 5. The transistors 11, 12 operate as complementary switches with typically at least one dead time intended to avoid a simultaneous conduction of these transistors 11, 12 in the arm of the converter.

Thus, outside of the dead times (intervals Tm=t2−t1, T′m=t6−t5 in the chronogram of FIG. 2), the signals S_{G1}, S_{G2} for controlling the first transistor 11 and the second transistor 12 are complementary or in phase opposition. These control signals SG1, SG2 allowing alternatingly to activate (i.e. turn on) then to deactivate (i.e. turn off) respectively the first transistor 11 and the second transistor 12 are applied respectively to the gate G1 of the first transistor 11 and to the gate G2 of the second transistor 12.

The measurement stage 20 of the control circuit allows to obtain the voltage drops in the transistors 11, 12 in the on state as well as a value of the current which passes through the transistors 11, 12 in the on state.

The control circuit can also be provided to, according to the values of measurements of drain source voltage V_{DS1_ON}, V_{DS2_ON} of the transistors in the on state and the current passing through the transistors in the on state, evaluate the dynamic resistance in the on state of the transistors 11, 12.

The control circuit can also be designed to, according to values of dynamic resistance in the on state of the transistors 11, 12, control their respective control signals S_{G1}, S_{G2}.

The measurement stage 20 of the control circuit is provided with a first measurement circuit 21 coupled to the first transistor 11 in order to determine the drain source voltage in the on state V_{DS1_ON} of the first transistor 11. This first measurement circuit 21 is provided here with an operational amplifier Op-Amp1 mounted in differential mode and according to a linear mounting, with an output looping onto its inverting input.

The operational amplifier Op-Amp1 is in particular mounted in differential mode 41 to produce at the output an output voltage Vds1_ON proportional to a difference in potentials between a drain electrode D1 potential of the first transistor 11 placed in the on state and a source electrode S1 potential of the first transistor 11 placed in the on state.

The operational amplifier Op-Amp1 is provided with an input coupled to a drain electrode D1 of the first transistor 11 and with another input coupled to a source electrode S1 of the first transistor 11. In the example illustrated, the source S1 is thus connected to the non-inverting input E+ of the operational amplifier Op-Amp1 while the drain D1 is coupled to the inverting input E− of the amplifier Op-Amp1.

A switch element 31 is arranged between the drain electrode D1 of the first transistor 11 and the input E− of the amplifier Op-Amp1. This switch element 31 is formed in this example by a coupling transistor M₁ here of the N type, the gate of which is controlled by a measurement control signal S_{M1}, to activate the coupling transistor M₁ during a measurement phase.

In order to avoid a circulation of current from the drain of the first transistor 11 towards the amplifier Op-Amp1, a current-blocking element such as a diode 33 is provided here in parallel with the coupling transistor M₁.

The switch element 31 is controlled (change of state in this example at a high potential of the measurement control signal S_{M1} applied to the gate of the coupling transistor M₁ at the time t₃) so as to couple the drain electrode D1 of the first transistor 11 to the amplifier consecutively to the first transistor 11 being made conductive (change of state in this example at a high potential of the signal S_{G1} of the transistor 11 at the time t₂). The measurement of drain source voltage is thus carried out while the first transistor 11 is made conductive. When the measurement phase is over, the measurement control signal S_{M1} is modified (change of state and setting to a low potential of the signal S_{M1} applied to the gate of the first transistor M₁ at the time t₄) so as to decouple the drain electrode D1 of the first transistor 11 from the amplifier Op-Amp1. Then, once the measurement phase is over, the control signal S_{G1} changes state (time t₅) so as to deactivate the first transistor 11. The measurement phase and the coupling of the first transistor 11 to the measurement stage 20 are thus only carried out when the first transistor 11 is activated (i.e. placed in the on state).

The measurement control signal S_{M1} can be produced on the basis of the signal S_{G1} allowing to control the gate of the first transistor 11, in particular by applying to this signal S_{G1} an adjustable predetermined delay T_{delay1b} when the latter is modified (here goes to a high state) so as to turn on the first transistor 11. When the measurement phase ends, the placing of the first transistor 11 back into the off state is triggered after a predetermined delay T_{delay2a}=t5−t4.

These delays T_{delay1b}, T_{delay2a} are provided in order to not disturb the switching behaviour of the first transistor 11 when its voltage drop is measured. These delays T_{delay1b}, T_{delay2a} can be approximately respectively ten nanoseconds and several tens of nanoseconds. Thus, the transistor M₁ of the measurement stage is activated about ten ns after the activation of the transistor 11 and turned off several tens of ns before the turning off of the transistor 11 is triggered. The control signal S_{M1} and the delays T_{delay1b}. T_{delay2a} can be respectively produced and modulated via a digital circuit of the microcontroller type or an FPGA and advantageously the same digital circuit as that producing the signals for controlling the transistors 11, 12.

The current passing through the first transistor 11 when it is made conductive is measured here via a circuit branch 24 coupled to a load R_LOAD. In said branch a load current I_{LOAD} that is an image of a current passing through the first transistor 11 in the on state. This branch 24 is connected to a middle point between the source S1 of the first transistor 11 and the drain D2 of the second transistor 12.

Insofar as the second transistor 12 is made non-conductive in other words is turned off when the first transistor 11 is made conductive, the load current I_{LOAD} is substantially equal or proportional to the current passing through the first transistor in the on state during the phase of measurement of VDS_ON1.

A current sensor 25, for example of the ACS712-30A type, allows to measure the current passing through the load after the middle point S1-D2.

The current sensor 25 allows to evaluate the current I_{LOAD} and consequently the current passing through the first transistor 11 in the on state.

The control circuit is, in this example, provided with a second measurement circuit 22 coupled this time to the second transistor 12 in order to determine the drain source voltage in the on state VDS2_ON of the second transistor 12.

The second measurement circuit 22 is advantageously provided with a configuration similar to that of the first measurement circuit 21 with an operational amplifier mounted in differential mode Op-Amp2 and including an input coupled to an electrode of the second transistor 12 and another input coupled to another electrode of the second transistor 12.

The two operational amplifiers mounted in differential mode Op-Amp1, Op-Amp2 are advantageously provided with a high slew rate, that is to say typically of at least 100V/us.

The two operational amplifiers Op-Amp1 and Op-Amp2 can be powered between V+ and V− and advantageously via an external battery 111. This allows to minimise the disturbances in the measurements.

The second circuit 22 is also provided with its switch element 32. Consecutively to an activation of the second transistor 12 (time to in FIG. 2), a second switch element 32 is controlled (change in level of the measurement control signal S_{M2} at the time t₇ in FIG. 2) so as to couple the second transistor 12 and the associated amplifier Op-Amp2 and a phase of measurement of the voltage V_{DS_ON2} starts. When this measurement phase is over (time t₈ in FIG. 2 when the measurement control signal S_{M2} changes level), the second switch element 32 is controlled so as to decouple the second transistor 12 from the amplifier Op-Amp2. Then, the second transistor 12 is deactivated (time to in FIG. 2 when the signal S_{G2} for controlling the second transistor changes level).

The current passing through the second transistor 12 while it is made conductive is measured via the branch 24 by evaluating using the current sensor 25 the load current I_{LOAD}. Insofar as the first transistor 11 is made non-conductive in other words is turned off when the second transistor 12 is made conductive, the load current I_{LOAD} is substantially equal or proportional to the current passing through the second transistor in the on state during the phase of measurement of V_{DS_ON2}.

The measurement phase and the coupling of the second transistor 12 to the measurement stage 20 are thus only carried out when the second transistor 12 is activated (i.e. placed in the on state).

In this exemplary embodiment a measurement of drain source resistance of the first transistor only when the latter is turned on, then a measurement of drain source resistance of the second transistor only when the latter is turned on are alternatingly carried out, the first transistor and the second transistor not being turned on simultaneous but alternatingly.

Advantageously, the coupling transistors M₁, M₂ allowing during the measurement phases to establish the connection between the GaN transistors 11, 12 and the measurement amplifiers Op-Amp1, Op-Amp2 are transistors of the MOSFET type chosen for their switching rapidity.

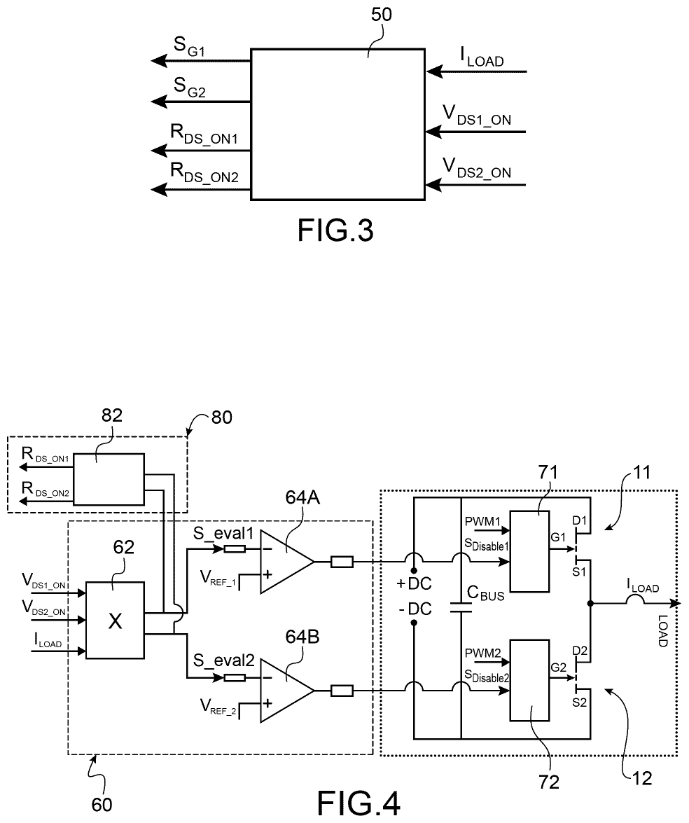

In FIG. 3, a stage 50 of the control circuit 20 is shown schematically. This stage 50 can be for example provided with a microcontroller or with an integrated circuit of the type with a network of programmable cells (FPGA for Field Programmable Gate Array). The stage 50 is provided with a calculation module configured to receive an output voltage VDS1_ON of the first amplifier 41 and to calculate a ratio between said output voltage VDS1_ON and said load current I_{LOAD} when the first transistor 11 is made conductive. This ratio thus gives a value of dynamic drain source resistance RDS_ON1 for the first transistor 11. Alternatively or in combination with a calculation module of a microcontroller or of an FPGA it is also possible to use an analogue divider to determination such a ratio. Using the aforementioned calculation module, the stage 50 is also configured to, on the basis of an output voltage V_{DS2_ON} of the first operational amplifier mounted in differential mode 41 and a load current I_{LOAD} when the second transistor 12 is made conductive, determine a ratio VDS2_ON/I_{LOAD} to thus determine a value of drain source resistance RDS_ON2 for the second transistor 12 when it is placed in the on state.

Advantageously, besides a monitoring of the values of drain source resistance in the on state, it is possible to provide protection of the transistors 11, 12 when these values reach levels that are too high.

The stage 50 can thus also be provided to modify the signals S_{G1}, S_{G2} for controlling the transistors 11, 12 according to the values of drain source resistance determined.

The stage 50 in particular when it includes a microcontroller or an integrated circuit of the type with a network of programmable cells (FPGA for “Field Programmable Gate Array”) can also be provided to produce the measurement control signals S_{M1}, S_{M2}.

In the specific exemplary embodiment illustrated in FIG. 4, the control circuit is further provided with a protection circuit 60. This protection circuit 60 is configured to, when the drain source resistance in the on state of the first transistor 11 exceeds a given threshold, allow to trigger a deactivation of the first transistor 11. This protection circuit 60 is also configured to, when the drain source resistance in the on state of the second transistor 12 exceeds a given threshold, allow to trigger a deactivation of the second transistor 12.

In the specific exemplary embodiment illustrated, the evaluation of the drain source resistances in the on state is carried out using an analogue multiplier 62 receiving at the input the load current I_{LOAD}, the output voltage V_{DS1_ON} of the first amplifier Op-Amp1, the output voltage V_{DS2_ON} of the second amplifier Op-Amp2. The multiplier 62 is capable of producing at the output a first evaluation signal S_eval1 representative of the ratio between said output voltage V_{DS1_ON} of the first amplifier Op-Amp1 and said load current I_{LOAD}, as well as a second evaluation signal S_eval2 representative of the ratio between said output voltage V_{DS2_ON} of the second amplifier Op-Amp2 and said load current I_{LOAD}.

The evaluation signals S_eval1, S_eval2 are here emitted at the input and in particular on the inverting input respectively of a first comparator 64A and of a second comparator 64B. As for the non-inverting inputs of the comparators 64A, 64B, they are respectively set to a fixed potential Vréf_1, Vréf_2 on which the given threshold depends.

According to the result of the comparison with a first fixed potential Vréf_1 (respectively a second fixed potential Vréf_2), the first comparator 64A (respectively the second comparator 64B) is configured to produce a first deactivation signal Sdisable1, (resp. a second deactivation signal Sdisable2) intended for a first gate pilot circuit 71 (resp. for a second pilot circuit 72) so as to deactivate the first transistor 11 (resp. the second transistor 12), the drain source resistance of which in the on state is too high.

The gate pilots 71, 72 are typically provided with a power amplifier and accept at the input a pulse width modulation signal PWM1, PWM2 (PWM for Pulse Width Modulation) coming from a digital circuit as mentioned above.

In this example the evaluation signals S_eval1, S_eval2 representative respectively of the dynamic drain source resistance R_{DS_ON1} of the first transistor 11 and of the dynamic drain source resistance R_{DS_ON2} of the second transistor 12 can be digitised and memorized via a monitoring and save circuit 80 provided with an analogue-digital converter stage and with at least one memory. This circuit 80 can be for example formed by a microcontroller or by an FPGA.

A monitoring of dynamic resistance in the on state of each GaN transistor is thus implemented and a saving of the data for analyses later can be carried out. A protection of the transistors 11 and 12 is also carried out in the case in which the critical dynamic resistance values are reached in order to avoid the destruction of components and/or of the system.

In the example described above in relation to FIG. 1, the transistors 11, 12 containing GaN belong to a power inverter arm. This can correspond for example to an arm of a 400 W solar micro power inverter, or more generally a DC/AC power inverter. It is also possible to apply a measurement of drain source resistance as described above to other types of circuits having GaN transistors and for example to other types of converters containing GaN components such as DC/DC converters.

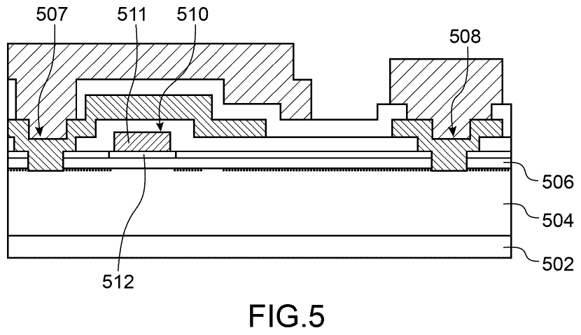

FIG. 5 now gives a schematic cross-sectional view of one possible structure of the first and of the second transistor 11, 12.

The transistor is made from a semiconductor substrate 502, for example containing silicon, on which a semiconductor block comprising a heterojunction is disposed. The heterojunction is made of a stack comprising a first layer 504 of a III-N semiconductor material having a first forbidden band and a second layer 506 of a III-N semiconductor material having a second forbidden band, larger than said first forbidden band. When the transistor contains GaN, the first layer 504 typically contains GaN while the second layer 506 can, for example, be made of AlGaN.

The transistor further comprises source 507 and drain 508 electric contacts, which are disposed on and in contact with regions of the layer 506. Each of the electric contacts 507 and 508 can be a metal layer or a stack of metal layers. A 2-DEG two-dimensional electron gas can be formed in a channel region located in the first layer 504, typically under the interface between the second layer 506 and the first layer 504.

The transistor further comprises a gate electrode 510 that is disposed in contact and here on a part of the second layer 506 to control the two-dimensional electron gas. The gate electrode 510 is formed by an upper region 511 that contains metal and that is in contact with a lower semiconductor region 512 for example containing p-GaN.

1. An electronic device provided with GaN transistors, the electronic device comprising:
a control circuit configured to evaluate the drain source resistance in an on state of at least one first transistor out of said transistors, the on or off state of the first transistor being controlled by a first control signal applied to a gate, said control circuit including:
a first circuit configured to measure drain source voltage in the on state of the first transistor, the first circuit comprising a first operational amplifier configured to produce at the output a first output voltage proportional to a difference in potentials between a drain electrode potential of the first transistor placed in the on state and a source electrode potential of the first transistor placed in the on state,
a first switch element arranged between a given electrode out of said source and drain electrodes of the first transistor and a first input of the first amplifier, the first switch element being configured to couple the given electrode to the first input of the first amplifier consecutively to a placement of the first transistor in the on state,
a circuit branch in which a load current that is an image of a current passing through the first transistor in the on state is capable of circulating, and
an evaluation stage configured to, on the basis of said load current and said output voltage, produce a first evaluation signal representative of a ratio between said output voltage and said load current.

2. The device according to claim 1, wherein the evaluation stage of the control circuit includes a digital calculation module integrated into a microcontroller or into an integrated FPGA circuit having a network of programmable cells or includes an analog divider or an analog multiplier.

3. The device according to claim 1, wherein the control circuit further includes a protection circuit, the protection circuit including a first comparator to compare said first evaluation signal to a given threshold, the protection circuit being configured to, when said first evaluation signal exceeds said given threshold, emit a deactivation signal so as to maintain said first transistor off.

4. The device according to claim 3, further comprising a first gate pilot circuit producing said first control signal, the deactivation signal being emitted at the input of said first gate pilot circuit.

5. The device according to claim 1, wherein among said transistors there is at least one second transistor coupled to the first transistor, a gate of the second transistor being controlled by a second control signal, the second control signal being, except for dead times, in phase opposition to the first control signal, said circuit branch being arranged between the first transistor and the second transistor so that the load current is the image of the current passing through the second transistor when the second transistor is in the on state,
said control circuit further including:
a second circuit configured to measure a drain source voltage in the on state of the second transistor, the second circuit comprising an operational amplifier, mounted in differential mode, called a second amplifier, to produce at the output an output voltage proportional to a difference in potential between a drain electrode potential of the second transistor placed in the on state and a source electrode potential of the second transistor placed in the on state, and
a second switch element arranged between the source or drain electrode of the second transistor and an input of the second amplifier, the second switch element being configured to couple the source or drain electrode of the second transistor and the input of the second amplifier consecutively to a placement of the second transistor in the on state,
said evaluation stage of the control circuit being further configured to, on the basis of said load current and said output voltage, produce a second evaluation signal representative of a ratio between the output voltage of the second transistor and said load current.

6. The device according to claim 5, wherein the control circuit includes a protection circuit and wherein the gate of the second transistor is controlled by a second gate pilot circuit, the protection circuit including a comparator to compare said second evaluation signal to another given threshold, the protection circuit being further configured to, when the second evaluation signal exceeds said other given threshold, emit a second deactivation signal at the input of a second gate pilot circuit so as to maintain said second transistor off.

7. The device according to claim 1, wherein the first switch element is controlled by a measurement triggering signal, the control circuit further comprising a stage for controlling the signal of the first control signal and of the measurement triggering signal to, consecutively to a change in state of the first control signal turning the first transistor on, trigger, after a first determined delay after the change, a state modification of the measurement triggering signal so as to turn the first switch element on and to, consecutively to a new state modification of the measurement triggering signal turning the first switch element off, trigger a new state change of the control signal turning the first transistor off.

8. The device according to claim 1, wherein the first differential amplifier is powered between a first positive power supply potential and a second negative power supply potential via an external battery.

9. A power inverter including the electronic device according to claim 1, the first transistor belonging to an arm of the power inverter.

10. A converter including the electronic device according to claim 1, the first transistor belonging to a switching cell of the converter.
